(19) United States
(12) Patent Application Publication
(10) Pub. No.: US 2025/0344575 A1
(43) Pub. Date: Nov. 6, 2025

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Xue Zhou, Wuhan, Hubei (CN); Yu GU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/862,163

(22) PCT Filed: Jun. 29, 2023
(86) PCT No.: PCT/CN2023/103535

§ 371 Date: Oct. 31, 2024

(30) Foreign Application Priority Data
Nov. 15, 2022 (CN) 202211429245.7

(51) Int. Cl. H10K 59/122; H10K 59/80; H10K 102/00

(52) U.S. Cl. CPC H10K 59/122; H10K 59/80515; H10K 59/80521; H10K 2102/351

(57) ABSTRACT

A display panel is provided, in which an inorganic layer is formed on the driving structure layer, a recessed portion is provided on the inorganic layer. A limiting opening of the pixel definition layer exposes an anode. An angle between a side of the recessed portion and a plane where the inorganic layer is located is a first angle, which is less than 90 degrees. An angle between a side wall of the limiting opening and a plane where the pixel definition layer is located is a second angle, which is less than 90 degrees and less than the first angle.

### TECHNICAL FIELD

The present disclosure generally relates to the field of display technology. More particularly, it relates to a display panel.

### BACKGROUND

Organic light-emitting diodes (OLED) have attracted the attention of many display manufacturers around the world due to their advantages of autonomous light emission, wide operating temperature range, fast response speed, wide viewing angle, high luminous efficiency, ability to be made on flexible substrates, low driving voltage and energy consumption, and are known as the next generation of display technology. With the continuous development of science and technology, the production technology of display panels is becoming more and more mature, while the market's requirements for power consumption and stability of panels are also getting higher.

During research and practical processes in the prior art, the inventors of this disclosure have discovered two issues. Firstly, OLED devices are prone to be affected by water and oxygen, which leads to a reduction in the lifespan of OLED devices. Secondly, in OLED panels, only a small portion of light can be radiated into the air and observed by human eyes, while most of the light is confined within the OLED panel due to substrate mode, waveguide mode, surface plasma mode, and material absorption, and therefore cannot be utilized, resulting in relatively low light emission efficiency of the OLED panel.

### SUMMARY

The embodiments of the present disclosure provide a display panel that can improve its service life and light emission efficiency.

An embodiment of the present disclosure provides a display panel, which comprises:
a substrate;
a driving structure layer, wherein the driving structure layer is disposed on the substrate;
an inorganic layer, wherein the inorganic layer is disposed on the driving structure layer, a recessed portion is disposed on the inorganic layer, and an angle between a side of the recessed portion and a plane where the inorganic layer is located is a first angle, which is less than 90 degrees;
an anode, wherein the anode is disposed on the inorganic layer and covers the recessed portion;
a pixel definition layer, wherein the pixel definition layer is disposed on the inorganic layer; the pixel definition layer is provided with a limiting opening, which exposes the anode and corresponds to the recessed portion, and an angle between a side wall of the limiting opening and a plane where the pixel definition layer is located is a second angle, which is less than 90 degrees and less than the first angle;
a luminescent layer, wherein the luminescent layer is disposed on the anode and within the limiting opening; and
a cathode, wherein the cathode is disposed on the luminescent layer and covers the recessed portion correspondingly.

Optionally, in some embodiments of the present disclosure, a depth of the recessed portion is less than or equal to a thickness of the inorganic layer.

Optionally, in some embodiments of the present disclosure, the first angle is greater than or equal to 30 degrees and less than or equal to 70 degrees, and the second angle is greater than or equal to 20 degrees and less than or equal to 40 degrees.

Optionally, in some embodiments of the present disclosure, the driving structure layer comprises a buffer layer, a thin film transistor layer and a planarization layer, the buffer layer is disposed on the substrate, the thin film transistor layer is disposed on the buffer layer, the planarization layer is disposed on the thin film transistor layer, and the inorganic layer covers the planarization layer;
and a thickness of the inorganic layer is between 0.025 times and 0.34 times a thickness of the planarization layer.

Optionally, in some embodiments of the present disclosure, in an area corresponding to the limiting opening, the inorganic layer comprises at least two divisions, and the recessed portion separates two adjacent divisions.

Optionally, in some embodiments of the present disclosure, the recessed portion is annular or grid shaped.

Optionally, in some embodiments of the present disclosure, in an area corresponding to the limiting opening, the inorganic layer comprises a middle area and edge areas disposed on the periphery of the middle area;
and a depth of the recessed portion located in the middle area is greater than a depth of the recessed portion located in the edge areas.

Optionally, in some embodiments of the present disclosure, a bottom width of the recessed portion is between 1 micron and 5 microns; a depth of the recessed portion is between 0.1 micrometers and 1 micrometer.

Optionally, in some embodiments of the present disclosure, in an area corresponding to the limiting opening, the inorganic layer comprises a middle area and edge areas disposed on a periphery of the middle area;
and a first angle of the recessed portion located in the middle area is greater than a first angle of the recessed portion located in the edge areas.

Optionally, in some embodiments of the present disclosure, in the cross-section of the display panel in the thickness direction, both the luminescent layer and the cathode corresponding to the area of the recessed portion form a first concave portion.

Optionally, in some embodiments of the present disclosure, the display panel further comprises a light extraction layer, a first inorganic encapsulation layer, an organic layer, and a second inorganic encapsulation layer sequentially covering the cathode;
and in the cross-section of the display panel in the thickness direction, both the light extraction layer and the first inorganic encapsulation layer corresponding to the area of the recessed portion form a second concave portion.

Optionally, in some embodiments of the present disclosure, a region of the planarization layer located at the recessed portion has a first roughness, a region of the planarization layer covered by the inorganic layer has a second roughness, and the first roughness is greater than the second roughness.

Optionally, in some embodiments of the present disclosure, the region of the planarization layer located at the recessed portion is formed with a microstructure.

Optionally, in some embodiments of the present disclosure, the microstructure is provided over the entire surface.

The embodiments of the present disclosure also provide a display panel, which comprises:
a substrate;
a driving structure layer, wherein the driving structure layer is disposed on the substrate;
an inorganic layer, wherein the inorganic layer is disposed on the driving structure layer, a recessed portion is disposed on the inorganic layer, and an angle between a side of the recessed portion and a plane where the inorganic layer is located is a first angle, which is less than 90 degrees;
an anode, wherein the anode is disposed on the inorganic layer and covers the recessed portion;
a pixel definition layer, wherein the pixel definition layer is disposed on the inorganic layer; the pixel definition layer is provided with a limiting opening, which exposes the anode and corresponds to the recessed portion, and an angle between a side wall of the limiting opening and a plane where the pixel definition layer is located is a second angle, which is less than 90 degrees and less than the first angle;
a luminescent layer, wherein the luminescent layer is disposed on the anode and within the limiting opening; and
a cathode, wherein the cathode is disposed on the luminescent layer and covers the recessed portion correspondingly.
wherein a depth of the recessed portion is less than or equal to a thickness of the inorganic layer, a bottom width of the recessed portion is between 1 micron and 5 microns, and a depth of the recessed portion is between 0.1 micrometers and 1 micrometer.

Optionally, in some embodiments of the present disclosure, the first angle is greater than or equal to 30 degrees and less than or equal to 70 degrees, and the second angle is greater than or equal to 20 degrees and less than or equal to 40 degrees.

Optionally, in some embodiments of the present disclosure, the driving structure layer comprises a buffer layer, a thin film transistor layer, and a planarization layer, the buffer layer is disposed on the substrate, the thin film transistor layer is disposed on the buffer layer, the planarization layer is disposed on the thin film transistor layer, and the inorganic layer covers the planarization layer;
and a thickness of the inorganic layer is between 0.025 times and 0.34 times a thickness of the planarization layer.

Optionally, in some embodiments of the present disclosure, in an area corresponding to the limiting opening, the inorganic layer comprises at least two divisions, and the recessed portion separates two adjacent divisions.

Optionally, in some embodiments of the present disclosure, the recessed portion is annular or grid shaped.

Optionally, in some embodiments of the present disclosure, in an area corresponding to the limiting opening, the inorganic layer comprises a middle area and an edge area disposed on the periphery of the middle area;
and a depth of the recessed portion located in the middle area is greater than a depth of the recessed portion located in the edge area.

Optionally, in some embodiments of the present disclosure, in an area corresponding to the limiting opening, the inorganic layer comprises a middle area and edge areas disposed on the periphery of the middle area;
and a first angle of the recessed portion located in the middle area is greater than a first angle of the recessed portion located in the edge areas.

Optionally, in some embodiments of the present disclosure, a region of the planarization layer located at the recessed portion has a first roughness, a region of the planarization layer covered by the inorganic layer has a second roughness, and the first roughness is greater than the second roughness.

### BENEFICIAL EFFECT

In the embodiments of the present disclosure, an inorganic layer is formed on a driving structure layer, the provision of a recessed portion on the inorganic layer, an anode is disposed on the inorganic layer and covers the recessed portion; a pixel definition layer is disposed on the inorganic layer; the pixel definition layer provides a limiting opening, which exposes the anode and corresponds to the recessed portion; a luminescent layer is disposed on the anode and located within the limiting opening; a cathode is disposed on the luminescent layer and correspondingly covers the recessed portion.

Through the recessed portion ac provided in the inorganic layer according to the first embodiment of the present disclosure, on the one hand, the display panel is waterproof and oxygen-resistant due to the material characteristics of the inorganic layer, thereby reducing the intrusion of water and oxygen from the planarization layer into the luminescent layer; on the other hand, due to the concave-convex structure of the film layers above the anode through the provision of the recessed portion, the propagation path of the light changes when light radiates to the concave-convex structure, thereby reducing the optical waveguide effect and enhancing the light emission efficiency of the display panel.

In addition, the embodiments of the present disclosure adopt the recessed portion formed on the inorganic layer. Compared to the recessed portion being formed in an organic layer such as a planarization layer, in the inorganic layer it is more likely to form a larger first angle θ under thinner thickness conditions, which can reduce difficulty and cost of the process. Moreover, a relatively large first angle θ can better improve the light emission effect of the panel.

### BRIEF DESCRIPTION OF THE DRAWINGS

In order to provide clearer explanations of the technical solutions in the embodiments of the present disclosure, it is to be noted that the drawings in the following description are merely some of embodiments of the present disclosure, and that other drawings may be obtained by the skilled person in the art without involving creative labor.

FIG. 1 is a schematic diagram of the structure of a display panel provided in a first embodiment of the present disclosure.

FIG. 2 shows the radiation pattern of light rays in the optical waveguide mode of the display panel provided in the first embodiment of the present disclosure.

FIG. 3 is a schematic diagram of a partial structure of the display panel provided in the first embodiment of the present disclosure.

FIG. 4 is a schematic diagram of the structure of the inorganic layer in a corresponding limiting opening in the display panel provided in the first embodiment of the present disclosure.

FIG. 5 is schematic diagram of another structural of the inorganic layer in a corresponding limiting opening in the display panel provided in the first embodiment of the present disclosure.

FIG. 6 is a schematic diagram of the structure of a display panel provided in a second embodiment of the present disclosure.

FIG. 7 is a schematic diagram of the structure of the display panel provided in a third embodiment of the present disclosure.

### DETAILED DESCRIPTION

The following will provide a clear and complete description of the technical solution in the embodiments of the present disclosure, combined with the accompanying drawings. It should be appreciated that, the described embodiments are only some of the embodiments of the present disclosure, not all of them. Based on the embodiments in this disclosure, all other embodiments obtained by those skilled in the art without creative labor fall within the scope of protection of the present disclosure. Furthermore, it should be appreciated that the specific embodiments described herein are only for illustration and explanation of the present disclosure and are not intended to limit the present disclosure. In the present disclosure, unless otherwise stated, directional words such as “up” and “down” usually refer to the up and down directions of the device in actual use or working conditions, specifically the direction of the figures in the accompanying drawings, and “inside” and “outside” refer to the outline of the device.

Embodiments of the present disclosure provide a display panel, which will be described in detail below. It should be noted that the order of describing the following embodiments is not intended to define the preferred order of the embodiments.

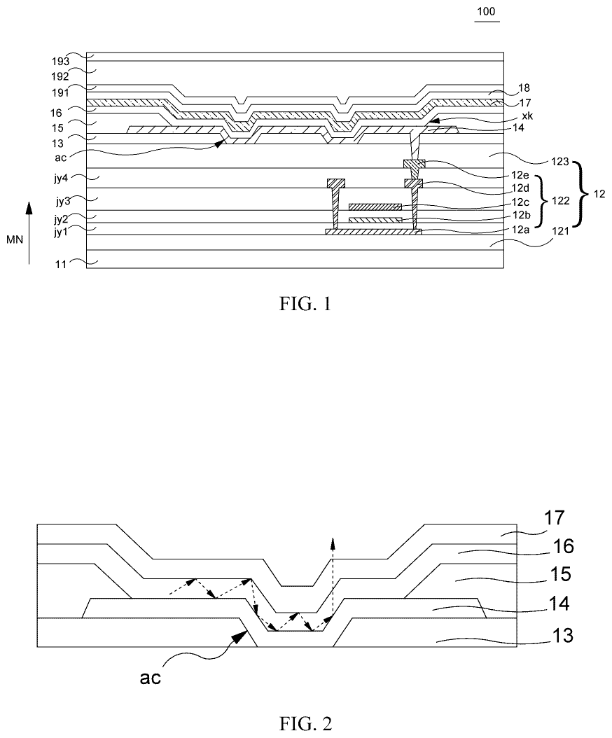

Referring to FIG. 1, an embodiment of the present disclosure provides a display panel 100, which comprises a substrate 11, a driving structure layer 12, an inorganic layer 13, an anode 14, a pixel definition layer 15, a luminescent layer 16, and a cathode 17.

The driving structure layer 12 is disposed on the substrate 11. The inorganic layer 13 is disposed on the driving structure layer 12, and the recessed portion ac is disposed on the inorganic layer 13. The anode 14 is disposed on the inorganic layer 13 and covers the recessed portion ac.

The pixel definition layer 15 is disposed on the inorganic layer 13. The pixel definition layer 15 has a limiting opening xk, which exposes the anode 14 and corresponds to the recessed portion ac. The luminescent layer 16 is disposed on the anode 14 and within the limiting opening xk. The cathode 17 is disposed on the luminescent layer 16 and correspondingly covers the recessed portion ac.

An angle between a side of the recessed portion ac and a plane where the inorganic layer 13 is located is a first angle θ, which is less than 90 degrees; an angle between a side of the limiting opening xk and a plane where the pixel definition layer 15 is located is a second angle α, which is less than 90 degrees; and the second angle α is smaller than the first angle θ.

Through the recessed portion ac provided in the inorganic layer 13 according to the first embodiment of the present disclosure, on the one hand, the display panel 100 is waterproof and oxygen-resistant due to the material characteristics of the inorganic layer 13, thereby reducing the intrusion of water and oxygen from the planarization layer into the luminescent layer 16; on the other hand, due to the concave-convex structure of the film layers above the anode 14 through the provision of the recessed portion ac, the propagation path of the light changes when light radiates to the concave-convex structure, thereby reducing the optical waveguide effect and enhancing the light emission efficiency of the display panel 100.

Specifically, in practical disclosures, the anode is made of reflective metal, and the cathode is made of a metal material with a certain transmittance. An optical microcavity is formed between the cathode and the anode. The light emitted by luminescent atoms in the luminescent layer generally emits in all directions, and some molecules with horizontal orientation are more conducive to light emissions, but cannot achieve 100% horizontal orientation. Therefore, under the action of charge injection and recombination, atoms will produce visible light in the forward range, as well as lateral emission limited in organic materials or pixel definition layers. This part of the light will be continuously reflected to form waveguide modes, however without the possibility of light emissions in the forward direction, thereby reducing the coupling efficiency of light emission. Now the anode 14 and the film layers above it have concave-convex structures, through which this part of the light can be emitted and herefore the light emission efficiency is improved, as shown in FIG. 2.

In addition, the embodiments of the present disclosure adopt the recessed portion ac formed on the inorganic layer 13. Compared to the recessed portion being formed in an organic layer such as a planarization layer, in the inorganic layer 13 it is more likely to form a larger first angle θ under thinner thickness conditions, which can reduce difficulty and cost of the process. Moreover, a relatively large first angle θ can better improve the light emission effect of the panel.

It should be understood that there are refractive index differences between the insulation film layers, and between the insulation film layers and the electrodes (anode and cathode). Due to the refractive index differences between the film layers, the optical waveguide effect occurs.

In the display panel 100 of the first embodiment, it can be understood that if the first angle θ is too small, the effect of improving the display panel's light emission efficiency is not significant. If the first angle θ is too large, climbing uniformity of the anode 14 is affected.

Therefore, in order to achieve good light emission efficiency of display panel 100 without affecting the uniformity of anode film formation, the first angle θ can be set within a range from 30 degrees to 70 degrees (i.e., 30 degrees≤first angle θ≤70 degrees). For example, the first angle θ can be 30 degrees, 45 degrees, 60 degrees, or 70 degrees, etc.

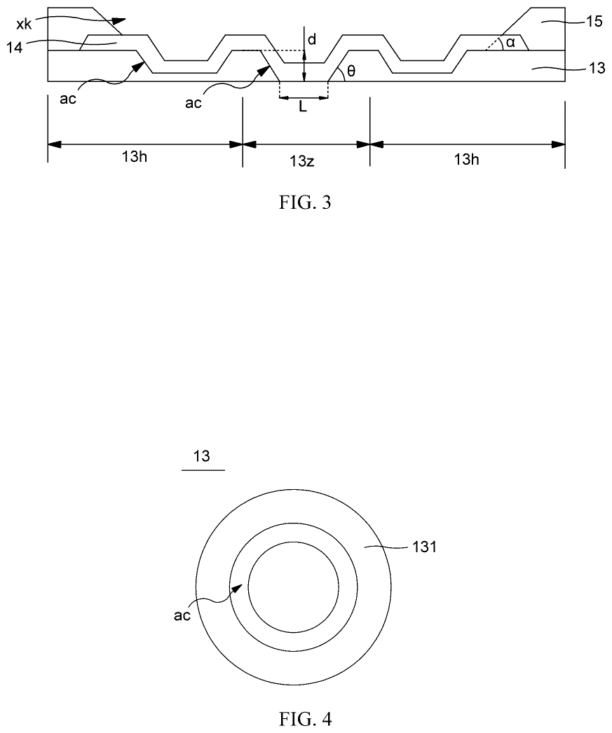

Please continue to refer to FIG. 3. It can be understood that if the second angle α is too small, the effect of improving the display panel's light emission efficiency will not be significant. If the second angle α is too large, the climbing continuity and uniformity of the luminescent layer 16 and cathode 17 is affected.

Optionally, the second angle α can be set within a range from 20 degrees to 40 degrees (i.e., 20 degrees≤second angle α≤40 degrees). For example, the second angle α can be 20 degrees, 30 degrees, or 40 degrees.

Optionally, substrate 11 can be a rigid substrate or a flexible substrate. The material of substrate 11 comprises any of glass, sapphire, silicon, silicon dioxide, polyethylene, polypropylene, polystyrene, polylactic acid, polyethylene dicarboxylate, polyethylene terephthalate, polyethylene naphthalate, polycarbonate, polyethersulfone, aromatic fluorotoluene containing polyarylate, polycyclic olefin, polyimide or polyurethane.

Optionally, the substrate 11 can be formed by stacking multiple films, or the substrate 11 can be a single-layer structure.

The driving structure layer 12 comprises a buffer layer 121, a thin film transistor layer 122, and a planarization layer 123. The buffer layer 121 is disposed on the substrate 11. The thin film transistor layer 122 is disposed on the buffer layer 121. The planarization layer 123 is disposed on top of the thin film transistor layer 122. The inorganic layer 13 covers the planarization layer 123.

The thickness of the inorganic layer 13 is between 0.025 times and 0.34 times the thickness of the planarization layer 123.

Therefore, in this embodiment, the recessed portion ac is formed in the inorganic layer 13. Compared to the recessed portion being formed at the same angle in an organic layer, the inorganic layer 13 can be made thinner and the difficulty of the process is reduced.

It should be understood that openings and other structures can be formed in the inorganic layer by a dry etching process.

Optionally, the thickness of the inorganic layer 13 is 0.025 times, 0.05 times, 0.1 times, 0.3 times, or 0.34 times the thickness of the planarization layer 123.

Optionally, the thickness of the planarization layer 123 can be between 3 microns and 4 microns, such as 3 microns, 3.5 microns, or 4 microns.

Optionally, the planarization layer 123 can be a multilayer formed by at least one organic material layer. However, the present disclosure is not limited to this. For example, the planarization layer 123 can be a single-layer organic material layer.

The thin film transistor layer 122 an active layer 12a, a first insulating layer jy1, a first metal layer 12b, a second insulating layer jy2, a second metal layer 12c, a third insulating layer jy3, a third metal layer 12d, a fourth insulating layer jy4 and a fourth metal layer 12e that are sequentially stacked on the buffer layer 121.

Optionally, the buffer layer 121, the first insulating layer jy1, the second insulating layer jy2, the third insulating layer jy3, the fourth insulating layer jy4, and the inorganic layer 13 can each be formed by stacking multiple layers of inorganic material in an alternating manner. For example, the buffer layer 121, the third insulating layer jy3, and the inorganic layer 13 can be formed as a double layer by stacking layers of inorganic material including at least one of silicon oxide (SiOx), silicon nitride (SiNx), silicon oxynitride (SiOxNy), aluminum oxide, magnesium oxide, and titanium oxide, or formed as a multilayer by alternately stacking layers of inorganic material including at least one of silicon oxide (SiOx), silicon nitride (SiNx), silicon oxynitride (SiOxNy), aluminum oxide, magnesium oxide, and titanium oxide. However, the present disclosure is not limited to this. The buffer layer 121, the third insulating layer jy3, and the inorganic layer 13 may be formed as a single-layer of inorganic material containing the above-mentioned insulating materials.

In addition, in one or more embodiments, the third insulating layer jy3 may be made of organic insulating materials such as polyimide (PI).

The materials of the fourth insulating layer jy4 and the planarization layer 123 can independently be organic transparent film layers, such as transparent photoresist, epoxy resin, polyimide, polyvinyl alcohol, polymethyl methacrylate, polystyrene, etc.

The material of the active layer 12a can be formed of single crystal silicon, polycrystalline silicon (poly-Si), or an oxide semiconductor.

The first metal layer 12b, the second metal layer 12c, the third metal layer 12d, and the fourth metal layer 12e are independently formed by at least one metal element of chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), cobalt (Co), or by alloys containing any of the above metal elements, or by alloys combining any of the above metal elements, etc. In addition, the first metal layer 12b, the second metal layer 12c, the third metal layer 12d, and the fourth metal layer 12e can have a single-layer structure or a multilayer structure with two or more layers.

Optionally, the first metal layer 12b comprises a gate. The third metal layer 12d comprises a source and a drain. The fourth metal layer 12e comprises a conductive pad. Herein, the drain or the source is connected to the conductive pad, and the conductive pad is connected to the anode 14.

Herein, in the embodiments of the present disclosure, the driving structure layer 12 can also be other architectures, such as a bottom-gate thin film transistor architecture, or a two-layer or three-layer metal layer architecture.

Optionally, as shown in FIG. 3, in the inorganic layer 13, the depth d of the recessed portion ac is less than or equal to the thickness of the inorganic layer 13.

It can be understood that when the depth d of the recessed portion ac is less than the thickness of the inorganic layer 13, the recessed portion ac is a groove. When the depth d of the recessed portion ac is equal to the thickness of the inorganic layer 13, the recessed portion ac is an opening.

When the recessed portion ac is a groove, in an area of the limiting opening xk, the inorganic layer 13 isolates the planarization layer 123 and the anode 14. When the recessed portion ac is an opening, in an area of the limiting opening xk, a region of the anode 14 contacts the planarization layer 123, which improves the stress release performance of the anode 14; and with limited depth d, compared to the groove scheme, the inorganic layer 13 can be thinned.

In some embodiments, it is also possible that part of the recessed portions ac is an opening, and part of the recessed portions ac may be a groove. Alternatively, a part of the recessed portion can be an opening and another part of the recessed portion can be a groove.

Optionally, in an area corresponding to the limiting opening xk, the inorganic layer 13 comprises a middle area 13z and edge areas 13h disposed on the periphery of the middle area 13z.

A depth of the recessed portion ac located in the middle area 13z is greater than that of the recessed portion ac located in the edge areas 13h, so that a part of the anode 14 corresponding to the middle area 13z has a deeper recessed structure compared to parts of the anode 14 corresponding to the edge areas 13h, which can not only improve the light emission efficiency, but can also reduce the risk of fracture of the anode 14 and the film layers above it near the side wall of the limiting opening xk, since the recessed portion ac corresponding to the edge areas 13h is very close to the side wall of the limiting opening xk and the recessed portion ac in this area is relatively shallow.

It can be understood that when the depth d of the recessed portion ac is too shallow, it has relatively small effect on changing the propagation path of light and cannot achieve the effect of improving the light emission efficiency. If the depth d of the recessed portion ac is too deep, it will affect the climbing continuity of the anode 14 and the uniformity of the cathode film formation.

In addition, if a bottom width L of the recessed portion ac is too narrow and the depth of the recessed portion ac is relatively deep, a pit in type of hole will be formed, which will affect the continuity and uniformity of the anode and luminescent layer film formation, and the control accuracy of the process is difficult to achieve. If the bottom width L of the recessed portion ac is too wide, it will sacrifice the light emission efficiency of the display panel to a certain extent.

Therefore, in this embodiment, the bottom width L of the recessed portion ac is between 1 micron and 5 microns. The depth d of the recessed portion ac is between 0.1 micrometers and 1 micrometer. With such arrangement, the light emission efficiency of the display panel is improved, and the continuity and uniformity of film formation of the anode 14 and the film layers above it are ensured.

Optionally, the bottom width L of the recessed portion ac can be 1 micron, 2 microns, 3 microns, 4 microns, or 5 microns, etc. The depth d of the recessed portion ac can be 0.1 micrometers, 0.2 micrometers, 0.3 micrometers, 0.4 micrometers, 0.5 micrometers, 0.6 micrometers, 0.7 micrometers, 0.8 micrometers, 0.9 micrometers, or 1 micrometer.

Optionally, the thickness of the inorganic layer 13 is less than or equal to 1 micrometer, such as 0.1 micrometer, 0.2 micrometer, 0.3 micrometer, 0.4 micrometer, 0.5 micrometer, 0.6 micrometer, 0.7 micrometer, 0.8 micrometer, 0.9 micrometer, or 1 micrometer.

The materials for the pixel definition layer 15 can be organic transparent film layers, such as transparent photoresist, epoxy resin, polyimide, polyvinyl alcohol, polymethyl methacrylate, polystyrene, etc.

When the material of the pixel definition layer 15 is polymer resin, due to the fluidity of polymer resin during thermal curing, the second angle α of the patterned pixel definition layer 15 that is formed by photolithography process is generally smaller than the first angle θ that is dry etched in the inorganic layer 13.

Optionally, at the same time, the second angle α is smaller than the first angle θ. Due to the use of vapor deposition technology to form the luminescent layer 16, the luminescent layer 16 is formed before the anode 14. The anode 14 is formed on the inorganic layer 13 and covers the recessed portion ac. In such case, the anode 14 compensates for the first angle θ to some extent, making the angle of the anode 14 corresponding to the recessed portion ac become smaller. Therefore, when the luminescent layer 16 is formed on the region of the anode 14 corresponding to the recessed portion ac and on the inner mouth wall of limiting opening xk of the pixel definition layer 15, the angle tends to be the same, which improves the uniformity of film formation of the luminescent layer 16 and enhances the light emission effect of the display panel 100.

Of course, the feature of the second angle α being smaller than the first angle θ can also be achieved by using other processes or adjusting process parameters according to different materials, so it is not limited in the present disclosure.

Optionally, the luminescent layer 16 can be formed from low molecular weight organic materials or high molecular weight organic materials such as PEDOT (poly (3,4-ethylenedioxythiophene)). The luminescent layer 16 can be a single-layer structure.

In addition, the luminescent layer 16 can also be formed from multiple layers including a hole injection layer (HIL), a hole transport layer (HTL), an electron transport layer (ETL), an electron injection layer (EIL), or an emission layer. When the luminescent layer 16 comprises all the above layers, the hole injection layer (HIL) is arranged on the anode 14, while the hole transport layer (HTL), the organic emission layer, the electron transport layer (ETL), and the electron injection layer (EIL) are stacked on the hole transport layer (HTL) in the given order.

Optionally, in the cross-section of the display panel 100 in the thickness direction MN, the luminescent layer 16 and the cathode 17 corresponding to the area of the recessed portion ac form a first concave portion respectively. This arrangement reduces the optical waveguide effect of the luminescent layer 16 and the cathode 17, further improving the light emission efficiency of the display panel 100.

The display panel 100 also comprises a light extraction layer 18, a first inorganic encapsulation layer 191, an organic layer 192, and a second inorganic encapsulation layer 193 sequentially covering the cathode 17.

In the cross-section of the display panel 100 in the thickness direction MN, the light extraction layer 18 and the first inorganic encapsulation layer 191 corresponding to the area of the recessed portion ac form a second concave portion respectively. This arrangement reduces the optical waveguide effect of the light extraction layer 18 and the first inorganic encapsulation layer 191, further improving the light emission efficiency of the display panel 100.

Please refer to FIGS. 4 and 5, which shows that in the area corresponding to the limiting opening xk, the inorganic layer 13 comprises at least two divisions 131, and the recessed portion ac separates two adjacent divisions 131.

This first embodiment uses a recessed portion ac to divide the inorganic layer 13 into multiple divisions 131, thereby improving the uniform light emission of the display panel 100.

Optionally, in the area corresponding to the limiting opening xk, the recessed portion ac can be in the form of a ring, a grid like, or a strip like, etc.

In some embodiments, the recessed portion ac may also be circular, square, or other shapes in the area corresponding to the limiting opening xk.

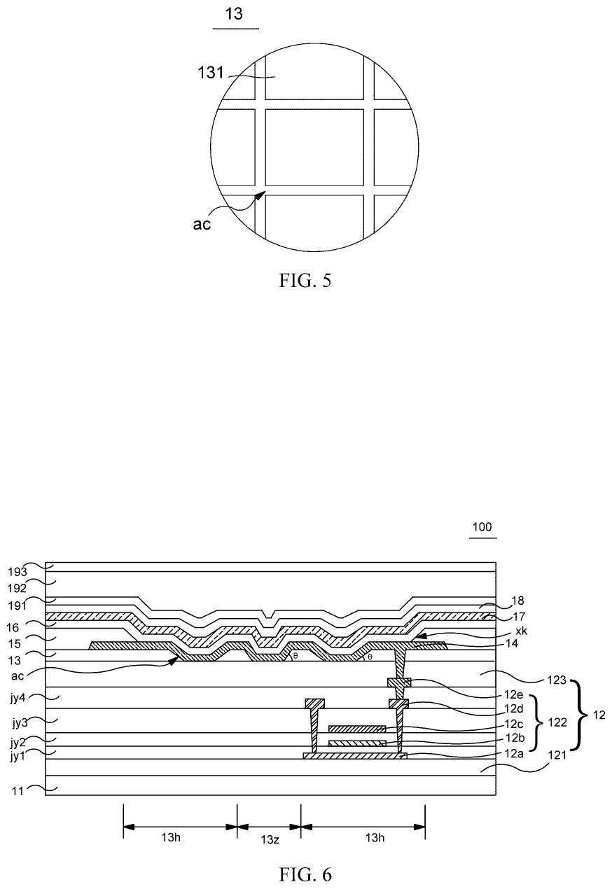

Please refer to FIG. 6, a difference between the display panel 100 of the second embodiment and the display panel 100 of the first embodiment is that: in the area corresponding to the limiting opening xk, the first angle θ of the recessed portion ac located in the middle area 13z is greater than the first angle θ of the recessed portion ac located in the edge area 13h.

This arrangement can improve the uniformity of light emission from the display panel 100.

It should be noted that this second embodiment can add the above distinguishing feature on the basis of the first embodiment; or it can add the above distinguishing feature on the basis that the depth of the recessed portion ac in the middle area 13z is equal to the depth of the recessed portion ac in the edge area 13h.

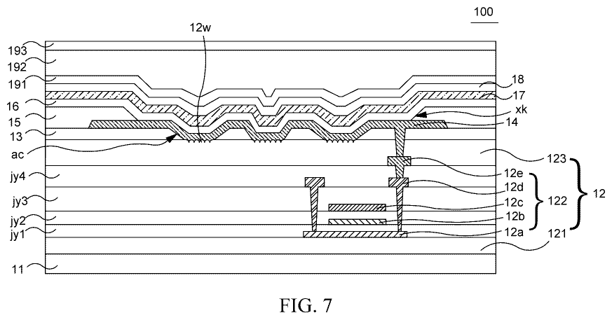

Please refer to FIG. 7, a difference between the display panel 100 of this third embodiment and the display panel 100 of the first embodiment or the second embodiment is that: a region of the planarization layer 123 located at the recessed portion ac has a first roughness, a region of the planarization layer 123 covered by the inorganic layer 13 has a second roughness, and the first roughness is greater than the second roughness.

That is to say, a microstructure 12w is formed in the region of the planarization layer 123 located at the recessed portion ac.

When the recessed portion ac is an opening, the opening exposes microstructure 12w. When the recessed portion ac is a groove, the bottom of the groove covers the microstructure 12w. By using the microstructure 12w corresponding to the recessed portion ac, when light radiates to the microstructure 12w, diffuse reflection will occur, further improving the light emission efficiency.

In an embodiment, a way to form the microstructure 12w can be to etch the exposed planarization layer 123 continually using etching gas that etches the inorganic layer 13, so that a part of the planarization layer 123 corresponding to the recessed portion ac forms the microstructure 12w. In such case, the recessed portion ac is an opening. Alternatively, the microstructure 12w can be formed on the planarization layer 123 first, and then the inorganic layer 13 can be formed on the planarization layer 123. This method can form microstructures 12w over a partial surface or an entire surface of the planarization layer 123.

In some embodiments, the microstructure 12w can also be formed over the entire surface of the planarization layer 123.

In the third embodiment of the present disclosure, the inorganic layer 13 is formed on the driving structure layer 12, and the recessed portion ac is provided on the inorganic layer 13. The anode 14 is disposed on the inorganic layer 13 and covers the recessed portion ac. The pixel definition layer 15 is disposed on the inorganic layer 13; the pixel definition layer 15 includes a limiting opening xk, which exposes the anode 14 and corresponds to the recessed portion ac. The luminescent layer 16 is provided on the anode 14 and within the limiting opening xk. The cathode 17 is disposed on the luminescent layer 16 and covers the corresponding recessed portion ac.

By providing the recessed portion ac in the inorganic layer 13, on the one hand, the display panel is waterproof and oxygen-resistant due to the material characteristics of the inorganic layer 13, thereby reducing the intrusion of water and oxygen from the planarization layer 123 into the luminescent layer; on the other hand, due to the concave-convex structures of the film layers above the anode 14 through the provision of the recessed portion, the propagation path of the light changes when light radiates to the concave-convex structure, thereby reducing the optical waveguide effect and enhancing the light emission efficiency of the display panel 100.

The above description introduces a display panel provided in the embodiments of the present disclosure in detail. Herein, specific examples are used to explain the principles and implementation methods of this disclosure. The descriptions of the above embodiments are only for helping to understand the method of this disclosure and its core ideas; meanwhile, for technical personnel in this field, there may be changes in the specific implementation methods and disclosure scope based on the ideas of this disclosure. In summary, the content of this specification should not be understood as limiting this disclosure.

1. A display panel comprising:
a substrate;
a driving structure layer, wherein the driving structure layer is disposed on the substrate;
an inorganic layer, wherein the inorganic layer is disposed on the driving structure layer, a recessed portion is disposed on the inorganic layer, and an angle between a side of the recessed portion and a plane where the inorganic layer is located is a first angle, which is less than 90 degrees;
an anode, wherein the anode is disposed on the inorganic layer and covers the recessed portion;
a pixel definition layer, wherein the pixel definition layer is disposed on the inorganic layer; the pixel definition layer is provided with a limiting opening, which exposes the anode and corresponds to the recessed portion, and an angle between a side wall of the limiting opening and a plane where the pixel definition layer is located is a second angle, which is less than 90 degrees and less than the first angle;
a luminescent layer, wherein the luminescent layer is disposed on the anode and within the limiting opening; and
a cathode, wherein the cathode is disposed on the luminescent layer and covers the recessed portion correspondingly.

2. The display panel according to claim 1, wherein a depth of the recessed portion is less than or equal to a thickness of the inorganic layer.

3. The display panel according to claim 2, wherein the first angle is greater than or equal to 30 degrees and less than or equal to 70 degrees, and the second angle is greater than or equal to 20 degrees and less than or equal to 40 degrees.

4. The display panel according to claim 2, wherein the driving structure layer comprises a buffer layer, a thin film transistor layer, and a planarization layer, the buffer layer is disposed on the substrate, the thin film transistor layer is disposed on the buffer layer, the planarization layer is disposed on the thin film transistor layer, and the inorganic layer covers the planarization layer; and
a thickness of the inorganic layer is between 0.025 times and 0.34 times a thickness of the planarization layer.

5. The display panel according to claim 2, wherein in an area corresponding to the limiting opening, the inorganic layer comprises at least two divisions and the recessed portion separates two adjacent divisions.

6. The display panel according to claim 5, wherein the recessed portion is annular or grid shaped.

7. The display panel according to claim 2, wherein in an area corresponding to the limiting opening, the inorganic layer comprises a middle area and an edge area disposed on periphery of the middle area; and
a depth of a first part of the recessed portion located in the middle area is greater than a depth of a second part of recessed portion located in the edge areas.

8. The display panel according to claim 2, wherein in the area corresponding to the limiting opening, the inorganic layer comprises a middle area and edge areas disposed on a periphery of the middle area; and
a first angle of a first part of the recessed portion located in the middle area is greater than a first angle of a second part of the recessed portion located in the edge areas.

9. The display panel according to claim 1, wherein a bottom width of the recessed portion is between 1 micron and 5 microns, and a depth of the recessed portion is between 0.1 micrometers and 1 micrometer.

10. The display panel according to claim 4, wherein a region of the planarization layer located at the recessed portion has a first roughness, a region of the planarization layer covered by the inorganic layer has a second roughness, and the first roughness is greater than the second roughness.

11. The display panel according to claim 10, wherein the region of the planarization layer located at the recessed portion is formed with a microstructure.

12. The display panel according to claim 11, wherein the microstructure is provided over the entire surface of the planarization layer 123.

13. A display panel comprising:
substrate;
a driving structure layer, wherein the driving structure layer is disposed on the substrate;
an inorganic layer, wherein the inorganic layer is disposed on the driving structure layer, a recessed portion is disposed on the inorganic layer, and an angle between a side of the recessed portion and the plane where the inorganic layer is located is a first angle, which is less than 90 degrees;
an anode, wherein the anode is disposed on the inorganic layer and covers the recessed portion;
a pixel definition layer, wherein the pixel definition layer is disposed on the inorganic layer; the pixel definition layer is provided with a limiting opening, which exposes the anode and corresponds to the recessed portion, and an angle between a side wall of the limiting opening and a plane where the pixel definition layer is located is a second angle, which is less than 90 degrees and less than the first angle;
a luminescent layer, wherein the luminescent layer is disposed on the anode and within the limiting opening; and
a cathode, wherein the cathode is disposed on the luminescent layer and covers the recessed portion correspondingly;
wherein a depth of the recessed portion is less than or equal to a thickness of the inorganic layer, and a bottom width of the recessed portion is between 1 micron and 5 microns, and a depth of the recessed portion is between 0.1 micrometers and 1 micrometer.

14. The display panel according to claim 13, wherein the first angle is greater than or equal to 30 degrees and less than or equal to 70 degrees, and the second angle is greater than or equal to 20 degrees and less than or equal to 40 degrees.

15. The display panel according to claim 13, wherein the driving structure layer comprises a buffer layer, a thin film transistor layer, and a planarization layer, the buffer layer is disposed on the substrate, the thin film transistor layer is disposed on the buffer layer, the planarization layer is disposed on the thin film transistor layer, and the inorganic layer covers the planarization layer; and
a thickness of the inorganic layer is between 0.025 times and 0.34 times a thickness of the planarization layer.

16. The display panel according to claim 13, wherein in an area corresponding to the limiting opening, the inorganic layer comprises at least two divisions, and the recessed portion separates two adjacent divisions.

17. The display panel according to claim 16, wherein the recessed portion is annular or grid shaped.

18. The display panel according to claim 13, wherein in an area corresponding to the limiting opening, the inorganic layer comprises a middle area and edge areas disposed on the periphery of the middle area; and
a depth of a first part of the recessed portion located in the middle area is greater than a depth of a second part of the recessed portion located in the edge areas.

19. The display panel according to claim 13, wherein in an area corresponding to the limiting opening, the inorganic layer comprises a middle area and edge areas disposed on the periphery of the middle area;
a first angle of a first part of the recessed portion located in the middle area is greater than a first angle of a second part of the recessed portion located in the edge areas.

20. The display panel according to claim 15, wherein a region of the planarization layer located at the recessed portion has a first roughness, a region of the planarization layer covered by the inorganic layer has a second roughness, and the first roughness is greater than the second roughness.
